(19) United States
(12) Patent Application Publication
(10) Pub. No.: US 2025/0368569 A1
(43) Pub. Date: Dec. 4, 2025

(54) SIGNAL FRIENDLY METALLIC SURFACES

(71) Applicants: UNIVERSITY OF SOUTH AUSTRALIA, Adelaide (AU); MALAYSIA AUTOMOTIVE ROBOTICS AND IOT INSTITUTE, Cyberjaya Selangor (MY)

(72) Inventors: Luqman YUNOS, Malacca (MY); Marta Llusca JANE, North Adelaide (AU); Peter J. MURPHY, Flagstaff Hill (AU); Kamil ZUBER, Salisbury Downs (AU)

(21) Appl. No.: 18/870,670

(22) PCT Filed: May 31, 2023
(86) PCT No.: PCT/AU2023/050472

§ 371 Date: Nov. 30, 2024

(30) Foreign Application Priority Data
May 31, 2022 (AU) 2022901475

(51) Int. Cl. C03C 17/36

(52) U.S. Cl. CPC C03C 17/366; C03C 17/3644; C03C 17/3649; C03C 17/3681; C03C 2217/212; C03C 2217/24; C03C 2217/256; C03C 2217/261; C03C 2218/156; C03C 2218/33

(57) ABSTRACT

The present disclosure relates to coated articles and their preparation methods. The coated article comprises a metallic layer, wherein the metallic layer bears a frequency selective surface configured to reduce attenuation of telecommunication frequency signal transmission.

### PRIORITY DOCUMENT

The present application claims priority from Australian Provisional Patent Application No. 2022901475 titled “COATED ARTICLES WITH A LOW-E COATING AND/OR A HARD COAT” and filed on 31 May 2022, the content of which is hereby incorporated by reference in its entirety.

### TECHNICAL FIELD

The present disclosure generally relates to coated articles and methods for their preparation. In a particular form, the present disclosure relates to coated articles comprising a metallic layer and having signal friendly transmission of telecommunication frequencies and methods for their preparation.

### BACKGROUND

A low emissivity (low-E) coating comprises a stack of very thin films that reflect solar infrared radiation and allow some of the visible light to pass through. Low-E coatings find applications in architectural glazing, automotive windows, and on solar thermal collectors due to their good energy saving performance. By way of example, the capability of low-e articles (such as windows) to reflect solar infrared radiation leads to a significant reduction of the indoor building temperature in summer, and maintains the indoor heat in winter, thus, minimising the use of air-conditioning and heating systems respectively. In addition, their high transmittance in the visible range greatly contributes to a reduction in need for artificial lighting during daylight hours.

To achieve this combination of reflectivity and transmittance, a low-E coating typically comprises conductive metallic layers and dielectric layers. In some circumstances, a multi-layer system of dielectric material(s)-silver-dielectric material(s) is used, wherein a thin layer (˜10 nm) of silver reflects long wavelength IR and the dielectric layers both protect the silver and provide anti-reflection functions. Common examples of dielectric materials include TiO₂, SnO₂ or ZnO, and they are typically deposited by magnetron sputtering.

For architectural windows, most commonly used coatings are low-E coatings. These do reflect the heat due to their metallic content and are highly transparent, but they are made of a rather complex structure, in which usually more than 20 layers and 10 different materials are involved, leading to an expensive manufacturing process. In addition, commercial low-E coatings suffer from durability issues due to corrosion at the IR reflective layer(s) that are usually made of silver (Ag), and therefore they are often placed inside the cavity between double pane windows to be protected from weathering.

Traditionally in the automotive industry, glass panes with an adhesive window tint that consists of one or more PET sheets which contain carbon, ceramic nanoparticles or a dark dye are used to darken windows to block IR radiation from the sun. However, these tints absorb the IR radiation instead of reflecting it. This means that the absorbed radiation is re-radiated back into a vehicle by conduction and convection, hence, not protecting the vehicle from the heat. In addition, they present low visible transmittance for an efficient heat blocking, thus, are not suitable for public transport or vehicle windscreens.

Another disadvantage of existing low-E coatings is that the thin metallic layer(s) attenuate(s) microwave and radiofrequency signals, especially high frequency ranges such as 5G wireless signals (600 MHz˜100 GHz). For instance, if a vehicle is equipped with metallic-based low-E windows, it will act as a Faraday cage and reflect or attenuate dramatically the useful telecommunication signals. With the evolution of wireless devices, it is also important to have a strong and steady signal strength inside buildings. The attenuation of the signal through an object is also measured by shielding effectiveness (SE). The shielding effectiveness is defined as the logarithm of the ratio of the magnitude of an incident electric field to the magnitude of the transmitted electric field and is expressed in decibels (dB). 0 dB means there is no attenuation. A current strategy to amplify the signal, for example, in public transport, is the installation of a repeater device. But this type of device only amplifies selected frequencies and needs to be replaced when the communication standards change. These are expensive and energy consuming. Another option is the use of ultra-wideband antennas, but their performance depends on the mounting location on the vehicle's body and the distance between the metallic window and the antenna can drastically reduce their efficiency. Antennas can also be integrated into heated windows. However, these will only cover the FM/TV range (50-800 MHZ). The latest integrated window antenna can cover 4G LTE and low frequency 5G signals, however, these also need to be replaced when communication standards change.

Articles (for example, windows and doors) having low-E coatings tend to be exposed to harsh and extreme conditions in practical applications and thus the resistance to weathering, robustness and durability are important.

There remains a need for coated articles and methods for their preparation that may alleviate or mitigate one or more of the above problems. In other words, it would be desirable for a coated article to have a simplified low-cost structure while preserving comparable transmittance of visible light and reflectivity of IR radiation to those of existing commercial products. In addition, or alternatively, it would be desirable for a coated article to have lower attenuation of the signal transmission of telecommunication frequencies. In addition, or alternatively, it would be desirable for a coated article to have improved durability and resistance to abrasion and weathering.

### SUMMARY

According to a first aspect, there is provided a coated article comprising a metallic layer, wherein the metallic layer bears a frequency selective surface configured to reduce attenuation of telecommunication frequency signal transmission.

In some embodiments, the metallic layer is a metallic IR reflective layer within a low-E coating comprised by the coated article.

In some embodiments, the frequency selective surface comprises a periodic pattern selected from the group consisting of a periodic hexagonal lattice, a periodic square lattice, a periodic triangular lattice, a periodic circular lattice, a periodic Kagome lattice and/or an aperiodic pattern such as a penrose tiling.

In some embodiments, the periodic pattern of the frequency selective surface has a unit cell dimension of less than about 2 mm, for example less than about 1 mm, and an aperture line width of about 5 μm to about 60 μm, for example about 30 μm to about 60 μm. In some further embodiments, the periodic pattern of the frequency selective surface has a unit cell dimension of about 0.5 mm and an aperture line width of about 50 μm. In even further embodiments, the frequency selective surface comprises a periodic hexagonal lattice which has a unit cell dimension of about 0.5 mm and an aperture line width of about 50 μm.

In some embodiments, the telecommunication frequency is for fifth-generation (5G) communication. In some further embodiments, the attenuation of telecommunication frequency signal transmission is reduced from about 30 dB to about 1 dB when compared with a coated article wherein the metallic layer bears no frequency selective surface.

In some embodiments, the metallic layer comprises silver (Ag), gold (Au), copper (Cu), aluminium (Al), zinc (Zn), niobium (Nb), titanium nitride (TiN), Ag/Au alloys, Ag/Cu alloys, Ag/Al alloys, NbNₓ, NbCr, NbCrNₓ, and/or NbZrOₓ. Silver (Ag), gold (Au) or copper (Cu) may be particularly suitable for the metallic IR reflective layer. In some further embodiments, the low-E coating comprises one metallic layer. In even further embodiments, the metallic layer has a thickness of about 5 nm to about 25 nm, preferably about 10 nm to about 20 nm.

In some embodiments, the coated article comprises a low-E coating supported by a substrate, and the low-E coating comprises, in order outward from the substrate, a dielectric layer, a protective layer, a metallic IR reflective layer as the metallic layer, a protective layer, and a dielectric layer.

In some embodiments, a substrate for the coated article is substantially made from plastic or glass, which may be flexible or rigid. In some specific embodiments, the plastic used for the substrate is selected from the group consisting of polycarbonate, polyethylene, polypropylene, ploymethylmethacrylate, polystyrene, polyamide, polyester, polyestercarbonate, polyethersulfone, polyethylene terephthalate (PET), polyethylene naphthalate (PEN), polyethylene terephthalate glycol (PETG), acrylonitrile butadiene styrene (ABS), acrylonitrile styrene acrylate (ASA), polymethyl methacrylate (PMMA) and polyetherimide. In some further embodiments, the glass used for the substrate is selected from the group consisting of borosilicate glass, flat glass, quartz glass, and soda lime (float) glass. In certain embodiments, the coated article has no between-pane space and the low-E coating is applied onto at least part of a surface of the substrate that will be exposed to a use environment. In some further embodiments, the substrate for the coated article has a thickness of about 0.4 cm to about 0.5 cm.

According to a second aspect, there is provided a method of reducing attenuation of telecommunication frequency signal transmission for a coated article comprising a metallic layer, wherein the method comprises creating a frequency selective surface on the metallic layer.

In some embodiments, the metallic layer is a metallic IR reflective layer within a low-E coating comprised by the coated article.

In some embodiments, the frequency selective surface comprises a periodic pattern selected from the group consisting of a periodic hexagonal lattice, a periodic square lattice, a periodic triangular lattice, a periodic circular lattice, a periodic Kagome lattice and/or an aperiodic pattern such as a penrose tiling.

In some embodiments, the periodic pattern of the frequency selective surface has a unit cell dimension of less than about 2 mm, for example less than about 1 mm, and an aperture line width of about 5 μm to about 60 μm, for example about 30 μm to about 60 μm. In some further embodiments, the periodic pattern of the frequency selective surface has a unit cell dimension of about 0.5 mm and an aperture line width of about 50 μm. In some further embodiments, the periodic pattern is a periodic hexagonal lattice and has a unit cell dimension of about 0.5 mm and an aperture line width of about 50 μm.

In some embodiments, the telecommunication frequency is for fifth-generation (5G) communication. In some further embodiments, the attenuation of telecommunication frequency signal transmission is reduced from about 30 dB to about 1 dB when compared with a coated article wherein the metallic IR reflective layer bears no frequency selective surface.

In some embodiments, a percentage of no more than about 25% area of the metallic layer is removed to create a frequency selective surface on the metallic layer. In some further embodiments, a percentage of no more than about 20% area of the metallic layer is removed to create a frequency selective surface on the metallic layer. In some further embodiments, a percentage of no more than about 10% area of the metallic layer is removed to create a frequency selective surface on the metallic layer. In even further embodiments, a percentage of about 5% to about 10% area of the metallic layer is removed to create a frequency selective surface on the metallic layer.

In some embodiments, a frequency selective surface is created on the metallic layer through laser etching or photolithography. In some further embodiments, one or more stack is subjected to laser etching to create a frequency selective surface on the metallic layer and the one or more stack is selected from the following: a stack of a substrate/a metallic layer, a stack of a substrate/a protective layer/a metallic layer, a stack of a substrate/a dielectric layer/a protective layer/a metallic layer, a stack of a substrate/a dielectric layer/a protective layer/a metallic layer/a protective layer, a substrate/a metallic layer/a substrate, a stack of a substrate/a protective layer/a metallic layer/a substrate, a stack of a substrate/a dielectric layer/a protective layer/a metallic layer/a substrate, and a stack of a substrate/a dielectric layer/a protective layer/a metallic layer/a protective layer/a substrate. In even further embodiments, for the laser etching, a laser beam enters from either side of the stack to create a frequency selective surface on the metallic layer. In even further embodiments, a multiple pane window comprising a metallic layer (for example, one or more metallic layer) is subjected to laser etching to create a frequency selective surface on the metallic layer.

According to a third aspect, there is provided a use of the coated article according to the first aspect or prepared according to the second aspect in automotive vehicles or buildings.

### BRIEF DESCRIPTION OF DRAWINGS

Embodiments of the present invention will be discussed with reference to the accompanying drawings wherein:

FIG. 1 shows an illustrative embodiment of a coated article comprising a simple, cost-effective and durable low-E coating supported by a polycarbonate substrate (0.4 cm) in accordance with the present disclosure.

FIG. 2 depicts a layer-by-layer structure of a coated article in accordance with the present disclosure, wherein the substrate/TiO₂/NiCr/Ag/NiCr has been laser etched with a honeycomb pattern.

FIG. 3 depicts application of a pulse laser beam to form a selective frequency surface on an Ag layer with different periodic patterns, wherein the darker area shows Ag coating, the bright area shows ablated line, D=diagonal length, and w=linewidth.

FIG. 4 shows photographs of the coated article of FIG. 1 before and after Bayer and Steel wool tests.

FIG. 5 shows low-E coating a) without hard coat after 24 hours in the salt spray tester, b) with hard coat after 1000 hours in the salt spray test.

FIG. 6 shows a) and b) photographs of laser etched 20 nm of Ag with the hexagonal pattern, and c) SEM image of the hexagonal pattern. Darkest areas correspond to ablated laser path.

FIG. 7 shows signal transmission in the automotive frequency range at 72 GHz to 82 GHz.

FIG. 8 shows transmittance and reflectance spectra of the full low-E coating with and without laser etching.

FIG. 9 shows that a laser beam enters from either side of a stack of a substrate (polycarbonate)/a dielectric layer (TiO₂)/a protective layer (NiCr)/a metallic layer (Ag) to create a frequency selective surface on the metallic layer.

FIG. 10 shows a schematic illustration of a photolithography process for fabricating a FSS hexagonal structure on a low-e coating.

### DESCRIPTION OF EMBODIMENTS

Aspects of the present disclosure arise from the inventors' research on a multifunctional coated article which may have a simple structure and are durable, visibly transparent, capable of reflecting thermal energy, efficient for 5G communications, as well as abrasion and weathering resistant. The coated article can be widely applied in, for example, automotive vehicles and buildings, such as in glazed windows for energy saving and efficient signal transmission.

The term “low emissivity (low-E)” used herein refers to a surface condition that emits low levels of radiant thermal energy and may have an emissivity value of about 0.04<ε<about 0.4. This ε implies the coated article may reflect at least about 60% up to about 96% of ultraviolet and infrared light that is incident on it.

The term “IR reflecting” used herein means capable of reflecting infrared (IR) radiation, especially near and medium IR radiation.

The term “telecommunication frequency” used herein includes, but not limited to, signals from about 600 MHz up to about 100 GHz, especially those for 5G communication, which allow for larger bandwidth, high data rates, lower latency and increased capacity on the network.

The term “frequency selective surface (FSS)” refers to a periodic resonant pattern designed on a coating that selectively allows or prevents the transmission of electromagnetic waves. For the present purpose, the frequency selective surface is particularly used to reduce attenuation of telecommunication frequency signal transmission.

The term “unit cell” with respect to a frequency selective surface used herein refers to a basic shape that forms a periodic pattern.

The terms “oxide”, “nitride” and “oxy-nitride” as used herein include various stoichiometries and, unless specified otherwise, includes all possible stoichiometries.

The symbol “x” or “y” in a chemical formula for a compound disclosed herein denotes the number of atoms of the element in question.

Disclosed herein is a coated article comprising a low-E coating supported by a substrate, wherein the low-E coating comprises a metallic IR reflective layer, a protective layer in contact with the metallic IR reflective layer, and a dielectric layer. The composition of the coated article disclosed can be chosen to make it transparent, and this may be desirable in the automotive, transportation or architectural industry.

For the present purpose, the coated article comprising the low-E coating may have a thermal emissivity ε of about 0.04<ε<about 0.4. Furthermore, the coated article may have a visible transmittance of >about 60%, preferably >about 70%, more preferably >about 80% and/or have an IR reflectance of >about 60%, preferably >about 70%. The low-E coating may be in a total thickness of about 90 nm to about 120 nm, for example 110 nm. The transmittance (% T) and reflectance (% R) are measured by a Cary 5000 spectrophotometer (Agilent Technologies) between 380 nm and 3300 nm. The visible solar weighted transmittance (% T_{VIS}) and IR solar weighted reflectance (% R_{IR}) were calculated as per eq. 1 and 2, respectively.

$$\% {T}_{VIS} = \frac{{\int }_{380}^{780} ( \% T \cdot Id λ )}{\int Id λ} \cdot 100 \qquad ( 1 )$$

$$\% {R}_{IR} = \frac{{\int }_{781}^{3300} ( \% R \cdot Id λ )}{\int Id λ} \cdot 100 \qquad ( 2 )$$

where I is the solar irradiance and dλ is the wavelength interval of integration.

The low-E coating disclosed herein can be directly or indirectly applied onto various substrates, which may be substantially made from plastic or glass. When the coated article is to be used as a window for buildings or vehicles, the substrate may preferably be transparent and have desirable optical qualities and impact resistance. The substrate may be coloured (e.g. green, grey or blue). The plastic substrate to be used may be rigid or flexible. For example, the low-E coating disclosed herein may be applied onto a flexible plastic substrate for window tints. Examples of suitable plastic substrates include, but are not limited to, polycarbonate, polyethylene, polypropylene, ploymethylmethacrylate, polystyrene, polyamide, polyester, polyestercarbonate, polyethersulfone, polyethylene terephthalate (PET), polyethylene naphthalate (PEN), polyethylene terephthalate glycol (PETG), acrylonitrile butadiene styrene (ABS), acrylonitrile styrene acrylate (ASA), polymethyl methacrylate (PMMA) and polyetherimide. Examples of glass substrates include, but are not limited to, borosilicate glass, flat glass, quartz glass, and soda lime (float) glass. Although a rigid glass substrate is well known, it is also possible for the glass substrate to be flexible, for example the Corning® Willow® Glass from Corning Inc., Corning, USA. Polycarbonate is a very robust plastic and naturally transparent, and may be a preferable option to replace glass. A suitable example is Makrolon® AR polycarbonate, which is commercially available from Covestro Group. The substrate to be used varies in thickness and may be about 0.4 cm to 0.5 cm thick.

It will be appreciated that the low-E coating may be coated on one side or two sides of the substrate. In certain embodiments, for a double glazed window, the low-E coating is applied on the inner side of each glazing pane. The coated article comprising the low-E coating and the hard coat disclosed herein advantageously has high abrasion and corrosion resistance, which in turn enables the low-E coating to be applied onto at least part of a surface of the substrate that will be exposed to a use environment and removes the need for it to be placed in between window panes. In other words, the coated article can have no between-pane space. The low-E coating reduces the amount of solar heat that passes through the coated article (for example, the window) to keep the inside cooler without compromising the amount of visible light that is transmitted. When the interior heat energy tries to escape to the colder outside during winter, the low-E coating reflects the heat back to the inside, thereby reducing radiant heat loss through the coated article. Methods known in the art can be used to apply one or more layers within the low-E coating onto the substrate. An example of the methods is physical vapor deposition (PVD), which includes, but is not limited to, magnetron sputtering, e-beam evaporation and thermal evaporation.

The low-E coating comprises one or more metallic IR reflective layer. Generally, the metallic IR reflective layers may comprise or consist of any reflective metal, such as silver (Ag), aluminium (Al), copper (Cu), zinc (Zn), niobium (Nb), titanium nitride (TiN), Ag/Au alloys, Ag/Cu alloys, Ag/Al alloys, NbNₓ, NbCr, NbCrNₓ, NbZrOₓ, and/or gold (Au). Preferably, silver (Ag) is utilised for the metallic IR reflective layer(s) due to its relatively neutral colour. The thickness of the metallic IR reflective layer can be selected to achieve the desired reflection and visible transmittance of IR radiation. On one hand, the reflective layer is expected to be thin enough to allow visible light through to provide good transmittance. On the other hand, the emissivity of a metallic IR reflective layer (such as Ag layer) tends to decrease with decreasing the sheet resistance. Thus, to obtain a low emissivity, the sheet resistance of the IR reflective layer(s) (such as Ag layer) should be as low as possible, which means as thick as possible in thickness. A thicker IR reflective layer may be beneficial for thermal performance, but it could lead to higher costs and longer time for fabricating the metallic IR reflective layer. In use, the thickness of the IR reflective layer may be from about 5 nm to about 25 nm, more preferably about 10 nm to about 20 nm. If desirable, two or three metallic IR reflective layers can be used. These are called double or triple reflective low-E coatings. The more reflective layers (e.g. Ag layers), the higher is the visible transmittance and the IR reflectance.

The metallic IR reflective layer can be applied using methods known in the art which include, but are not limited to, magnetron sputtering deposition and pyrolytic processes. In certain embodiments, an IR reflective layer may be sputtered (for example at about 3000W) onto a protective layer or a dielectric layer over the substrate from a cathode of a required metal in an inert atmosphere. An IR reflective layer fabricated through magnetron sputtering deposition generally performs better than the one fabricated through pyrolytic process in terms of solar control and the reduction of heat transfer through windows.

Various protective layers can be applied onto each metallic IR reflective layer to provide the latter with immediate protection, for example, against attack of the plasma when sputtering the dielectric layer(s) on top of it, or from the diffusion of aggressive species like O₂, O, H₂O, and Na⁺. It is also desirable for the protective layer to have good adhesion to the metallic IR reflective layer and allow satisfactory transmission of visible light. A metal, an alloy, a silicide, a nitride or any other suitable material that achieves the desired effect could be used. For example, the protective layer may comprise or consist of, without limitation, nickel-chromium alloys (NiCr), NiCrOₓ, NiCrNₓ, NiCrOₓN_{y}, NiₓTi_{y}O_{z}, Ni, Cr, CrNₓ, NiOₓ, Ti, TiOₓ, NbOₓ, ZnO, Al₂O₃, ZnALOₓ or any combination thereof. The nickel-chromium alloys (NiCr) include, but are not limited to, NiCr (80/20 wt. %), NiCr (70/30 wt. %), NiCr (60/40 wt. %) and NiCr (50/50 wt. %). In some situations, the protective layer may also serve as an adhesion and/or nucleation layer. With respect to all embodiments herein, each protective layer may be of a thickness in the range from about 1 nm to about 5 nm, preferably about 1 nm to about 3 nm or about 2 nm to about 3 nm. A thicker protective layer may contribute to durability. If the protective layer is too thin, it is likely to be uncontinuous and not be able to cover the metallic IR reflective layer, and therefore it will be ineffective in providing sufficient protection. In some embodiments, it is preferable to have a protective layer on each side of the IR reflective layer. However, the presence of a protection layer only on one side of the IR reflective layer is possible. In a preferable embodiment, the protective layer comprises NiCr. More preferably, a protective layer consisting of NiCr is provided on each side of the IR reflective layer.

Known methods, for example, sputtering deposition and thermal evaporation, can be used to apply the protective layer on the substrate. When a protective layer of NiCr is employed, the protective layer is preferably sputtered on the metallic IR reflective layer (for example at about 700W) and deposited from for example DC (direct current) targets. When a protective layer of ZnO is employed, the protective layer can be fabricated by arc plasma deposition with an evaporated zinc source, using a plasma containing a stoichiometric excess of oxygen.

A dielectric layer in the low-E coating performs anti-reflection functions and increases transmission of the overall coated article. It also provides protection to the layer(s) underneath. If needed, the low-E coating may comprise one or more dielectric layer. In some embodiments, a succession of two or more dielectric layers is used.

There is no specific limitation on the dielectric material(s) to be used for the dielectric layer. Most of the commonly used dielectric materials may be considered for the purpose of the present disclosure, for example, an oxide, a nitride, an oxy-nitride, or a combination thereof. It is also possible for the dielectric material to be doped with suitable materials, such as, Al or stainless steel. Factors including refractive index n, region of transparency, the availability of a deposition method and cost-effectiveness may be considered in choosing a suitable dielectric material. Other considerations such as compatibilities with other materials and thermal stability may also be decisive. Materials suitable for a dielectric layer include TiO₂, Ta₂O₅, Nb₂O₅, ZrO₂, ZnO, ZnS, ZnSe, HfO₂, LaTiO₃, Al₂O₃, La₂O₃, Y₂O₃, Gd₂O₃, Sc₂O₃, Si₃N₄, and SiAlOₓN_{y} and may comprise one or more selected from SiO₂, Al-doped SiO₂, LiF, MgF₂, Na₃AlF₆, SnO₂, indium tin oxide (ITO), Al-doped zinc oxide (AZO), WO₃, SiOₓN_{y}. For the purpose of high transmittance and refractive index, the protective layer preferably comprises or consists of TiO₂, Nb₂O₅, and/or Ta₂O₅. If desirable, a dielectric layer of SiO₂ or Al-doped SiO₂ may also function as an adhesive layer.

In general, the thickness of each of the dielectric layers is tuned to reduce inside and outside reflectance so that the light transmittance is high, for example, >about 60%. The thickness of each of the dielectric layers may vary from about 25 nm to about 45 nm. However, it is recommended that the thickness of each of the dielectric layers over the IR reflective layer is in the range of from about 30 nm to about 40 nm.

A dielectric layer used herein can be deposited by methods known in the art, such as radio frequency magnetron sputtering, direct current magnetron sputtering, reactive pulsed magnetron sputtering, thermal evaporation, electron-beam evaporation, ion-beam sputtering, and atomic layer deposition. The choice of the deposition method may depend upon the deposited material and the expected optical properties. In some embodiments, when a dielectric layer comprising TiO₂ and/or a dielectric layer comprising SiO₂ are to be deposited, magnetron sputtering is adopted (for example at about 3000W or 3800W for TiO₂, and at about 2000W for SiO₂) and the layers are prepared by sputtering Ti or Si target in oxygen.

In some embodiments, a metallic IR reflective layer is sandwiched between two adjacent protective layers, each of the protective layers comprises or consists of NiCr and is about <5 nm thick, the metallic IR reflective layer comprises or consists of Ag and is about 20 nm thick.

In some embodiments, the coated article disclosed herein comprises a low-E coating supported by a substrate, and the low-E coating comprises, in order outward from the substrate, a dielectric layer comprising or consisting of TiO₂, a protective layer comprising or consisting of NiCr, a metallic IR reflective layer comprising or consisting of Ag, a protective layer comprising or consisting of NiCr, and a dielectric layer comprising or consisting of TiO₂. If needed, a dielectric/adhesive layer comprising or consisting of SiO₂ or Al-doped SiO₂ is added onto the dielectric layer comprising or consisting of TiO₂ which is further outward from the substrate.

More specifically, the coated article comprises a low-E coating supported by a substrate, and the low-E coating may comprise, in order outward from the substrate, a dielectric layer of TiO₂ that is about 25 nm to about 45 nm, a protective layer of NiCr that is about <5 nm, a metallic IR reflective layer of Ag that is about 10 nm to about 20 nm, a protective layer of NiCr that is about <5 nm, and a dielectric layer of TiO₂ that is about 25 nm to about 45 nm. In even further embodiments, the coated article comprises a low-E coating supported by a substrate, and the low-E coating comprises, in order outward from the substrate, a dielectric layer of TiO₂ that is about 40 nm, a protective layer of NiCr (80/20) that is about <5 nm, a metallic IR reflective layer of Ag that is about 20 nm, a protective layer of NiCr (80/20) that is about <5 nm, and a dielectric layer of TiO₂ that is about 40 nm. In even further embodiments, the coated article comprises a low-E coating directly supported by a substrate, and the low-E coating comprises or consists of, in order outward from the substrate, a dielectric layer of TiO₂ that is about 40 nm, a protective layer of NiCr (80/20) that is about <5 nm, a metallic IR reflective layer of Ag that is about 20 nm, a protective layer of NiCr (80/20) that is about <5 nm, a dielectric layer of TiO₂ that is about 40 nm, and a dielectric/adhesive layer of SiO₂ or Al-doped SiO₂ that is about 10 nm.

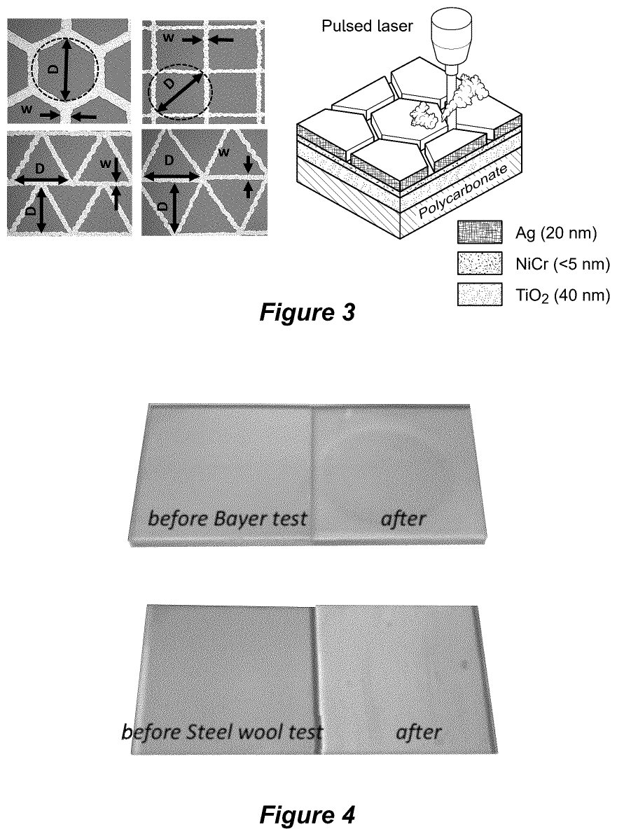

A frequency selective surface on the metallic IR reflective layer is used to enhance the transmission of telecommunication frequencies through the coated article. The frequency selective surface may have a periodic pattern, such as a periodic triangular lattice, a periodic square lattice, a periodic hexagonal lattice, a periodic circular lattice, or a periodic Kagome lattice (see FIG. 3). In addition or alternatively, the frequency selective surface may have an aperiodic pattern such as a penrose tiling. The frequency selective properties can be tuned by changing the geometrical shape and the geometrical parameters (such as the unit cell dimension and the aperture line width) of the periodic pattern so as to achieve desirable signal transmission at a particular operating frequency. The frequency selective surface used for the present purpose could advantageously reduce the attenuation of the signal transmission of telecommunication frequencies from about 30 dB to about 1 dB when compared with a coated article wherein the metallic IR reflective layer bears no frequency selective surface.

The unit cell dimension used herein refers to a dimension of the unit cell that reflects the periodicity and the aperture line width means the width of an ablated path. Taking a periodic hexagonal lattice as an example, the unit cell dimension is denoted by the length of a diagonal (see, for example, FIG. 2). For a periodic square lattice, the unit cell dimension is denoted by the diagonal of the square. For a periodic ring lattice, the unit cell dimension is denoted by a diameter. Preferably, the aperture line width is small enough so that the optical contrast is not visible to the naked eye.

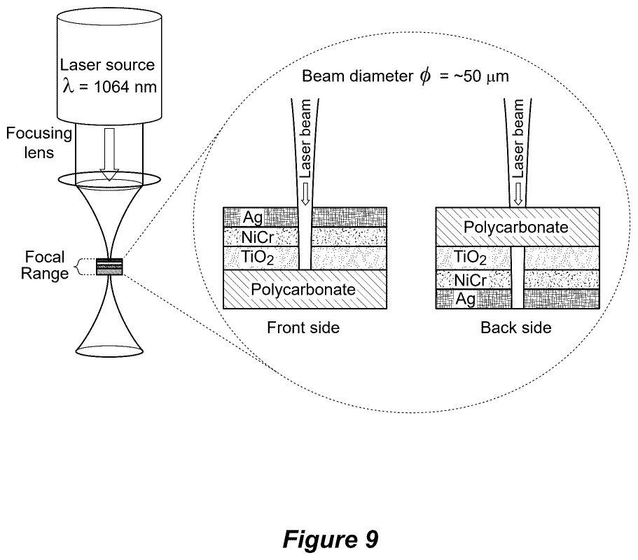

The frequency selective surface can be fabricated by laser etching. For this purpose, one or more stack may be subjected to laser etching to create the frequency selective surface on the metallic layer and the stack(s) may be selected from the following: a stack of a substrate/a metallic layer, a stack of a substrate/a protective layer/a metallic layer, a substrate/a dielectric layer/a protective layer/a metallic layer, a stack of a substrate/a dielectric layer/a protective layer/a metallic layer/a protective layer, a stack of a substrate/a metallic layer/a substrate, a stack of a substrate/a protective layer/a metallic layer/a substrate, a stack of a substrate/a dielectric layer/a protective layer/a metallic layer/a substrate, and a stack of a substrate/a dielectric layer/a protective layer/a metallic layer/a protective layer/a substrate. For the laser etching, it is possible for a laser beam to enter from any suitable side of the coated article in order to create a frequency selective surface on the metallic layer. As shown in FIG. 9, a laser beam may enter from the substrate side of the coated article or from the opposite side to the substrate of the coated article. This enables a fully assembled multiple pane window comprising a metallic layer to be subjected to laser etching and thereby to create a frequency selective surface on the metallic layer. If needed, a laser-scribed grid can be utilised in the fabrication. For the purpose of illustration, a stack of a substrate/a dielectric layer/a protective layer/a metallic IR reflective layer/a protective layer is etched by pulsed Nd: YAG laser before growing one or more layer such as another dielectric layer and an outermost hard coat over the protective layer. In some embodiments, a stack of a substrate/a dielectric layer/a protective layer/a metallic IR reflective layer is laser etched to create a frequency selective surface. The laser parameters can be optimised to etch just the metallic IR layer without reaching the substrate. Alternatively, photolithography may be considered to create the frequency selective surface. For example, a UV photolithography process can be carried out to transfer a pattern from a mask on a photoresist (light-sensitive material) followed by a wet etching process to create the frequency selective surface. By ablating only a small percentage in area of the IR reflective layer (for example 5% to 10% of the layer surface area), the thermal heat reflectance properties and the high transmittance of the coated article are preserved while allowing telecommunication frequencies to pass through.

In some embodiments, the periodic pattern of the frequency selective surface has a unit cell dimension of less than about 2 mm, for example less than 1 mm, and an aperture line width of about 5 μm to about 60 μm, for example about 30 μm to about 60 μm, for example 50 μm. It may be desirable that the periodic pattern of the frequency selective surface has a unit cell dimension of about 0.5 mm and an aperture line width of about 50 μm. In a preferable embodiment, the periodic pattern of the frequency selective surface is a periodic hexagonal lattice. More preferably, the diagonal of the hexagon is about 0.5 mm and the aperture line width is about 50 μm.

It has been found by the present inventors that a hard coat can be provided as an outermost layer to protect the layers underneath so as to improve durability (especially in terms of the abrasion resistance and weathering resistance) of the coated article. This in turn enables the coated article to be applied in automotive, medical and architecture applications. To this end, a variety of abrasion resistant hard coats based on polysiloxane may be considered, and they may typically be applied at a thickness of about 5 μm to about 6 μm. In some embodiments, the polysiloxane-based abrasion resistant hard coat can be prepared from a thermally curable, liquid polysiloxane nanocomposite hard coat resin containing silica nanoparticles, such as CRYSTALCOAT™ MP-101 commercially available from SDC TECHNOLOGIES ASIA PACIFIC, PTE. LTD. If needed, an adhesive layer may be applied onto the low-E coating before applying the hard coat and the adhesive layer can be made from materials known in the art, for example, SiO₂ or Al-doped SiO₂. If an adhesive layer of SiO₂ or Al-doped SiO₂ is adopted, the thickness of the adhesive layer can be about 10 nm to about 100 nm, preferably about 10 nm. A dip coating method or a flow coating method can be used to apply a polysiloxane based hard coat. For a dip coating, the substrate receives the coating prior to being thermally cured.

When there is no hard coat, the coated article comprising the low-E coating can be placed in the cavities of multiple pane windows so as to be isolated from the atmosphere.

Other layer(s) may also be present for the coated article disclosed herein. In some circumstances, instead of a hard coat, the coated article comprises an overcoat for example made from SiO₂ as the outmost layer to realise improved durability.

It will be appreciated that a method of reducing attenuation of telecommunication frequency signal transmission for a coated article is also disclosed herein, wherein the coated article comprises a metallic layer and the method comprises creating a frequency selective surface on the metallic layer. The metallic layer can be a metallic IR reflective layer within a low-E coating comprised by the coated article. The coated article and the frequency selective surface can be designed and fabricated with reference to the discussions made above.

In some circumstances, the coated article according to the present disclosure may allow 5G signals to pass through while effectively reflecting infrared light or thermal heat and being highly transparent, which makes it useful in windows for public transportation and buildings etc. It may also have a simplified design (in particular having as few as five to seven coating layers in some circumstances) compared to existing commercial products. It may enable the low-E coating to be applied onto at least part of a surface of the substrate that will be exposed to a use environment (i.e. facing the atmosphere) and removes the need for it to be placed in between panes.

### EXAMPLES

Fabrication of a Coated Polycarbonate Substrate with a Low-E Coating

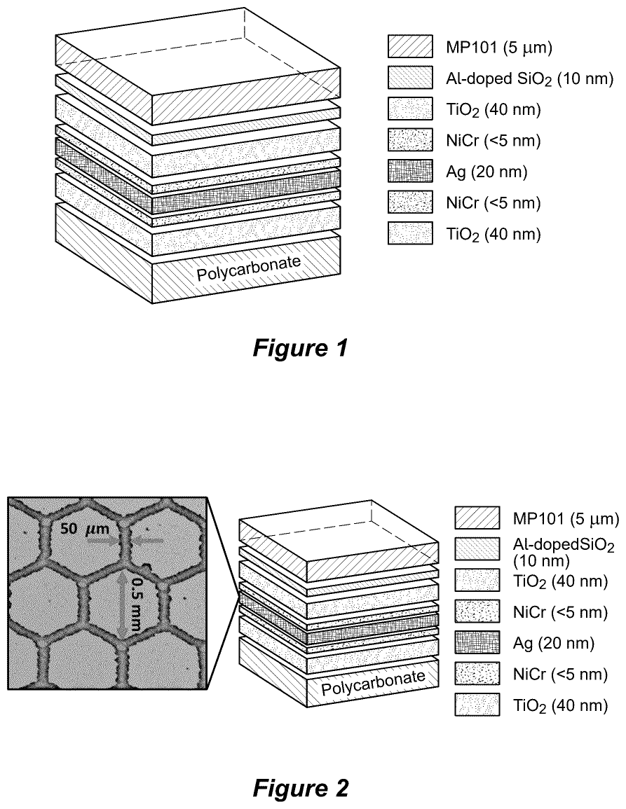

A coated polycarbonate as shown in FIG. 1 is prepared in the following way.

Makrolon AR polycarbonate (PC) substrates have been washed with detergent and a non-abrasive sponge, dried with compressed air and plasma cleaned in an Ar atmosphere for 2 minutes.

The deposition of TiO₂, NiCr, Ag and Al-doped SiO₂ was performed by means of a custom-made in-line magnetron sputtering system. The system uses high purity tubular sputtering targets (80 cm in height and 7.5 cm in diameter) that rotate during the deposition: Ti (99.99 wt % pure), NiCr (80 wt % Ni, 20 wt % Cr), Si (Al doped 5 wt %) and Ag (99.99 wt % pure). The pressure prior to deposition was 1.5×10⁻⁶ mbar and each target was pre-sputtered during 4 minutes.

Firstly, 40 nm of TiO₂ were deposited in poison mode using 400 sccm of Ar and 35 sccm of O₂ which gave a working pressure of 0.00595 mbar. The sputtering power was kept at 3800 W and the speed of the carrier was 1.04 mm/second.

Then, less than 5 nm of NiCr were deposited at 700 W at a working pressure of 0.00369 mbar (400 sccm of Ar) and at a carrier speed of 39.4 mm/second.

On top of NiCr, Ag (20 nm) was sputtered at 3000 W at the same working pressure, 0.00369 mbar, and carrier speed of 21.4 mm/second.

Again, NiCr (<5 nm) and then TiO₂ (40 nm) were grown on top of the patterned Ag, using previously defined conditions. 10 nm of Al-doped SiO₂ was deposited also in poison mode, at 2000 W, using 400 sccm of Ar and 45 sccm of O₂ which resulted in a working pressure of 5.1×10⁻³ mbar. The speed of the carrier was 16.4 mm/second.

And finally, a Qualtech QPI-168 dip coater was used to dip-coat the stacks with a transparent hard coat resin, CrystalCoat MP101 (SDC Technologies, solid content 32.5%) consisting of a siloxane matrix with embedded silica nanoparticles. An immersion rate of 500 mm/minute was used, which resulted in a hard coat thickness of 5 μm. After the immersion, the samples were allowed to dry for 30 minutes and then cured in an oven at 130° C. for 1 hour. This process was performed at a humidity of 25-45%.

FIG. 8 shows that the resultant low-E coating has a visible transmittance of about 61% and an IR reflectance of about 64%. Compared to some commercial low-E coatings, the low-E coating prepared herein not only has a simple low-cost structure but also demonstrates a comparable transmittance of visible light and a comparable reflectivity of IR radiation. The visible transmittance and the IR reflectance were analysed using a UV-VIS-NIR spectrophotometer (Cary 5000) from Agilent Technologies Inc.

### Durability-Abrasion and Corrosion of the Coated Article Prepared Above

Abrasion tests such as Bayer and Steel Wool tests were performed on the low-E samples. The Steel Wool test was conducted by a Sutherland® 2000™ Rub Tester from Danilee Co. In the Bayer test, a TABER® Oscillating Abrasion Tester (Model 6100) was used to assess abrasion resistance to fine gravel. In these tests, the higher is the abrasion ratio, the more resistant is the sample. Both tests confirmed the suitability of the coated article as first surface windows due to its high abrasion resistance (FIG. 4). Almost no visual changes were observed after the tests.

| | Bayer | Steel wool |
|---|---|---|
| ΔT(VIS)/% | 4.84 | −0.93* |
| $Ratio = \frac{Δ Haze Bare PC}{Δ Haze UniSA sample}$ | 6.26 | 18.29 |

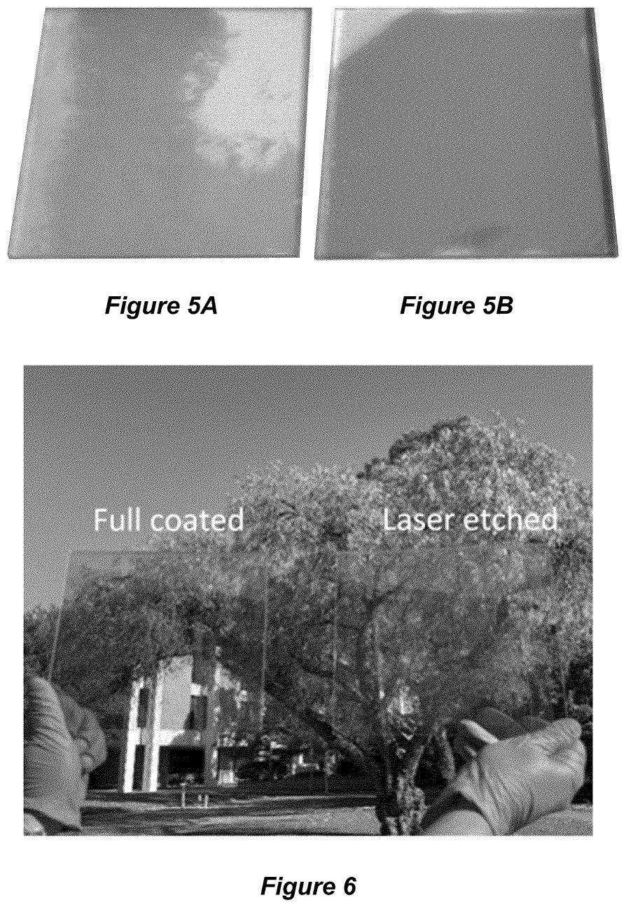

The low-E stack was placed 1000 hours inside a corrosion chamber. After 1000 hours (time required for commercial automotive side mirrors), the low-E coating had barely changed its appearance and resulted in the same transmittance values. FIG. 5 a) shows the result of the unprotected stack (without hard coat) after 24 hours inside the corrosion chamber and of the protected stack after 1000 hours.

Fabrication of a Coated Polycarbonate Substrate with a Low-E Coating Having a Frequency Selective Surface on the Metallic IR Reflective Layer Through Laser Etching

Makrolon AR polycarbonate (PC) substrates have been washed with detergent and a non-abrasive sponge, dried with compressed air and plasma cleaned in an Ar atmosphere for 2 minutes.

The deposition of TiO₂, NiCr, Ag and Al-doped SiO₂ was performed by means of a custom-made in-line magnetron sputtering system. The system uses high purity tubular sputtering targets (80 cm in height and 7.5 cm in diameter) that rotate during the deposition: Ti (99.99 wt % pure), NiCr (80 wt % Ni, 20 wt % Cr), Si (Al doped 5 wt %) and Ag (99.99 wt % pure). The pressure prior to deposition was 1.5×10⁻⁶ mbar and each target was pre-sputtered during 4 minutes.

Firstly, 40 nm of TiO₂ were deposited in poison mode using 400 sccm of Ar and 35 sccm of O₂ which gave a working pressure of 0.00595 mbar. The sputtering power was kept at 3800 W and the speed of the carrier was 1.04 mm/second.

Then, less than 5 nm of NiCr were deposited at 700 W at a working pressure of 0.00369 mbar (400 sccm of Ar) and at a carrier speed of 39.4 mm/second.

On top of NiCr, Ag (20 nm) was sputtered at 3000 W at the same working pressure, 0.00369 mbar, and carrier speed of 21.4 mm/second.

The frequency selective surface (FSS) is first designed by means of AutoCAD. The pattern designs are saved as a drawing exchange format (DXF) file and then transferred to the laser ablation equipment. The periodic FSS hexagonal patterns (unit cell 0.5 mm) are ablated and evaporated from the Ag thin films by a Nd: YAG (1064 nm) pulsed laser, G8 from Sei Laser. The patterns are etched at a frequency of 10 kHz with a speed of 100 mm/second and at a power of 18 W. These parameters produce an ablated linewidth of 50 μm. An extraction system is attached to the machine to remove fumes from the evaporation process.

Again, NiCr (<5 nm) and then TiO₂ (40 nm) were grown on top of the patterned Ag, using previously defined conditions.

10 nm of Al-doped SiO₂ were deposited also in poison mode, at 2000 W, using 400 sccm of Ar and 45 sccm of O₂ which resulted in a working pressure of 5.1×10⁻³ mbar. The speed of the carrier was 16.4 mm/second.

And finally, a Qualtech QPI-168 dip coater was used to dip-coat the stacks with a transparent hard coat resin, CrystalCoat MP101 (SDC Technologies, solid content 32.5%) consisting of a siloxane matrix with embedded silica nanoparticles. An immersion rate of 500 mm/minute was used, which resulted in a hard coat thickness of 5 μm. After the immersion, the samples were allowed to dry for 30 minutes and then cured in an oven at 130° C. for 1 hour. This process was performed at a humidity of 25-45%.

Characterisation of a Coated Polycarbonate Substrate with a Low-E Coating Having a Frequency Selective Surface on the Metallic IR Reflective Layer

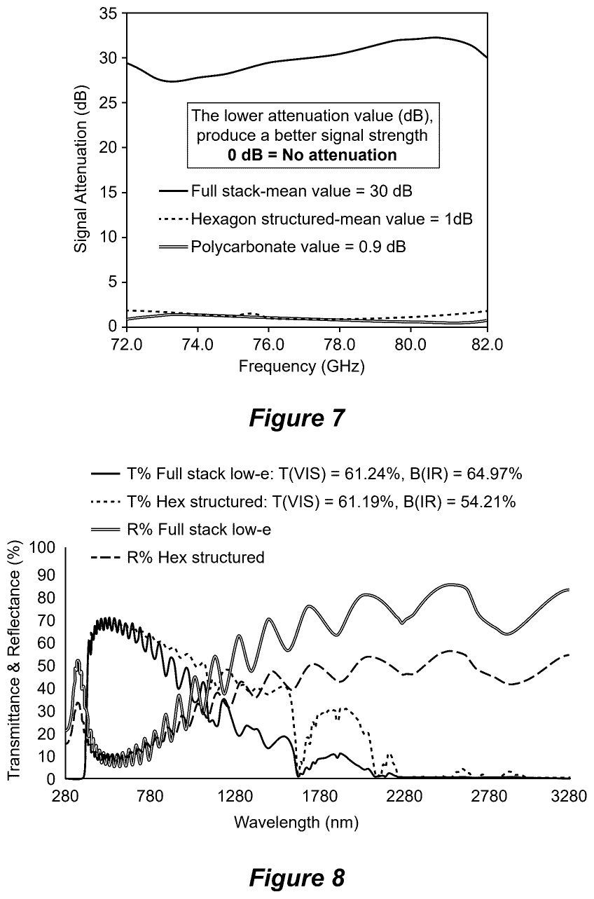

FIG. 7 and the table below provide characters of the coated article having a frequency selective surface and make comparison with plain polycarbonate and the coated article without a frequency selective surface.

| | One way | | | |
|---|---|---|---|---|
| | attenuation | | Infrared | Visible light |
| | (mean value | | blocking | transmission |
| Sample | 76-81 GHz) | | (%) | (%) |
| Plain Polycarbonate | 0.9 | dB | 18 | 87 |
| Full stack | 30 | dB | 64 | 61 |
| Full stack + Hexagon | 1 | dB | 54 | 62 |
| structured | | | | |
| (size = 0.5 mm, | | | | |
| linewidth = 50 μm) | | | | |

The FSS technique has also been applied to the fully grown low-E coating (FIG. 2). TiO₂/NiCr/Ag/NiCr films have been laser etched with the hexagonal pattern before growing top TiO₂, Al-doped SiO₂ and the hard coat. The transmittance of the resultant low-E coating has barely changed and the blocked IR light has just decreased by 10% (FIG. 8).

Fabrication of a Coated Polycarbonate Substrate with an Ag Film Bearing a Frequency Selective Surface

Commercial transparent hard-coated PC from Bayer (Makrolon® Abrasion Resistance-AR), 100 mm×100 mm and 4.5 mm thick, was used as the substrate. The dielectric constant (permittivity value) of the PC substrate is 2.96 (Technical data sheet, 2023). Before growing an Ag film, the PC substrates were washed with soap and rinsed with reverse osmosis (RO) water, then plasma treated for 2 minutes in order to remove any contaminants (Alder et al., 2020). Ag thin films, 10 nm thick, were deposited on the previously cleaned PC substrates by using an ion assisted electron-beam evaporation system, Satis Vacuum 725. The substrates were mounted on a rotating stage which moved at 90 rpm at 750 mm above the evaporant while being bombarded by Ar ions at a pressure of 1×10⁻⁴ mbar. Ag pellets (99.99% pure) from Kurt J. Lesker Company were placed inside a tungsten crucible and were evaporated at 1.4 Å/s. The thickness and deposition rate were monitored in real-time by using a quartz crystal oscillator (Sycon Instruments, STC-2000A). Although a low-e coating consists of several layers, in this example just a single Ag thin layer, which is responsible for the signal attenuation in low-e coatings, was employed to analyse the effect of the patterns.

Several FSS patterns were designed by means of AutoCAD 2021 (AutoCAD, 2021) and Solidworks 2019 (SOLIDWORKS, 2019) software. The same software programs were used to measure the amount of metallic area removed from the coating (%). The pattern designs were saved as a drawing exchange format (DXF) file and then transferred to the laser ablation equipment.

A laser ablation method was used to create the FSS patterns. The periodic patterns were ablated and evaporated from the Ag thin films by a Nd: YAG (1064 nm) pulsed laser, G8 from Sei Laser (G8, 2008). The frequency, power, and speed of the ablation process were optimised to avoid damaging the PC substrate, and to obtain the thinnest possible linewidth, hence, the patterns were etched at a frequency of 10 kHz with a speed of 100 mm/second and at a power of 18 W. These parameters produced an ablated linewidth of 50±10 μm and a clean ablated area. An extraction system was attached to the machine to remove fumes from the evaporation process.

Various FSS patterns with regular polygonal shapes (e.g., triangle, square and hexagon) were laser etched on Ag-coated PC substrates. The 5G attenuation value (72-82 GHZ), the optical properties and the morphology of the patterns were analysed to determine which one provides the lowest attenuation without compromising the IR reflectance and visible transmittance. The signal attenuation value (72-82 GHz) was measured by using an automotive radome tester (R&S®QAR by Rohde ε Schwarz).

Characterisation of a Coated Polycarbonate Substrate with an Ag Coating Bearing a Frequency Selective Surface

| | | Attenuation | Infrared | Visible light |
|---|---|---|---|---|
| | | value | blocking | transmission |
| Sample | Size | (−dB) | (%) | (%) |
| periodic | D = 0.5 mm | ~1.0 | 54 ± 2 | 61 ± 2 |
| hexagonal | w = 50 ± 10 | | | |
| lattice | μm | | | |
| periodic | D = 0.5 mm | ~1.0 | 44 ± 2 | 61 ± 2 |
| square | w = 50 ± 10 | | | |
| lattice | μm | | | |
| periodic | D = 0.5 mm | ~1.0 | 42 ± 2 | 61 ± 2 |
| triangular | w = 50 ± 10 | | | |
| lattice 1 | μm | | | |
| periodic | D = 0.5 mm | ~1.0 | 42 ± 2 | 61 ± 2 |
| triangular | w = 50 ± 10 | | | |
| lattice 2 | μm | | | |

Fabrication of a Coated Polycarbonate Substrate with a Low-E Coating Having a Frequency Selective Surface on the Metallic IR Reflective Layer Through Photolithography Process

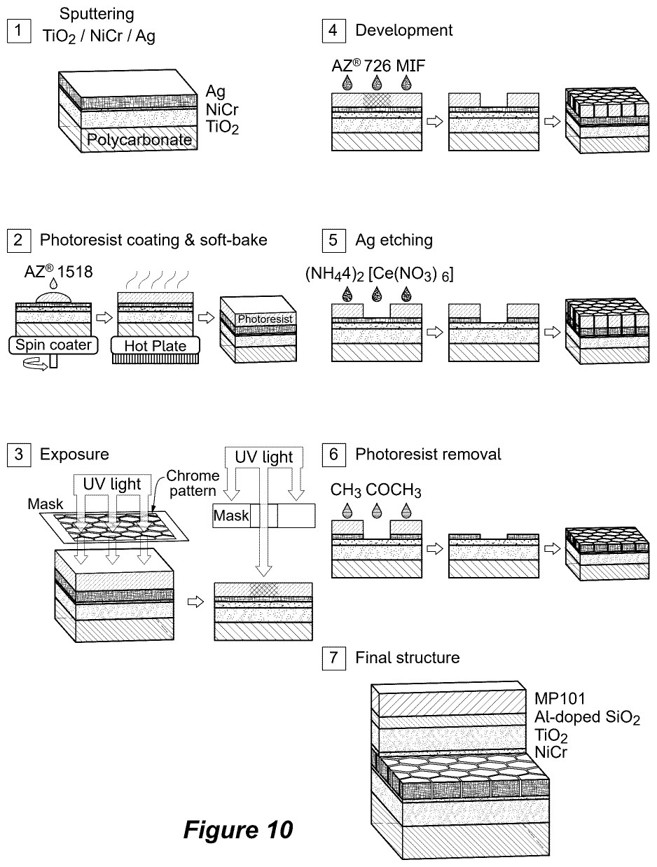

The following photolithography process is also illustrated in FIG. 10.
(1) A stack of a PC substrate/TiO₂/NiCr/Ag was prepared in the same way as described for the coated polycarbonate substrate with a low-E coating having a frequency selective surface on the metallic IR reflective layer through laser etching.
(2) A positive-photoresist liquid (AZ® 1518) was spin-coated onto the films. Then, the sample was cured on a hot plate for 1 minute at 100° C. to crosslink the photoresist (soft bake process). The thickness of the photoresist was approximately 1 μm.
(3) A mask alignment system (EVG®620) was used to expose the UV light (365 nm) through a mask with hexagonal patch patterns (D=0.5 mm, w=5 μm). The mask (from JD Photo Data) consisted of soda-lime glass with a chrome pattern on top, which selectively allowed UV light through, selectively treating the material. The UV light that passed through the mask induced chemical changes in the photoresist and modified the structure.
(4) A developer solution (AZR 726 MIF) was applied on the surface, and it dissolved the photoresist regions that were exposed to UV light, leaving the hexagonal patch patterns on the photoresist layer.
(5) To transfer the hexagonal pattern on the Ag layer, a wet etching technique was used by placing the sample in an etching chemical solution (ammonium cerium (IV) nitrate−(NH₄)₂[Ce(NO₃)₆]) for 1 minute 30 seconds. The etching solution penetrated into the hexagonal voids and completely removed the Ag layer.
(6) After the desired pattern was completed, the remaining photoresist was removed by rinsing with an acetone solution (CH₃COCH₃). Compressed air was sprayed just after rinsing to dry the sample and remove any etchant or acetone residue.
(7) After the patterning process on the Ag layer, the sample was coated with the other layers (NiCr/TiO₂/SiO₂/MP101).

The resultant low-E coating supported by the substrate had a visible transmittance of about 64% and an IR reflectance of about 65%. The 5G attenuation value (72-82 GHz) thereof was about 5.7 dB.

The reference to any prior art in this specification is not, and should not be taken as, an acknowledgement or any form of suggestion that such prior art forms part of the common general knowledge.

It will be understood that the terms “comprise” and “include” and any of their derivatives (e.g. comprises, comprising, includes, including) as used in this specification, and the claims that follow, is to be taken to be inclusive of features to which the term refers, and is not meant to exclude the presence of any additional features unless otherwise stated or implied.

In some cases, a single embodiment may, for succinctness and/or to assist in understanding the scope of the disclosure, combine multiple features. It is to be understood that in such a case, these multiple features may be provided separately (in separate embodiments), or in any other suitable combination. Alternatively, where separate features are described in separate embodiments, these separate features may be combined into a single embodiment unless otherwise stated or implied. This also applies to the claims which can be recombined in any combination. That is a claim may be amended to include a feature defined in any other claim. Further a phrase referring to “at least one of” a list of items refers to any combination of those items, including single members. As an example, “at least one of: a, b, or c” is intended to cover: a, b, c, a-b, a-c, b-c, and a-b-c.

It will be appreciated by those skilled in the art that the disclosure is not restricted in its use to the particular application or applications described. Neither is the present disclosure restricted in its preferred embodiment with regard to the particular elements and/or features described or depicted herein. It will be appreciated that the disclosure is not limited to the embodiment or embodiments disclosed, but is capable of numerous rearrangements, modifications and substitutions without departing from the scope as set forth and defined by the following claims.

1. A coated article comprising a metallic layer, wherein the metallic layer bears a frequency selective surface configured to reduce attenuation of telecommunication frequency signal transmission.

2. The coated article according to claim 1, wherein the metallic layer is a metallic IR reflective layer within a low-E coating comprised by the coated article.

3. The coated article according to claim 1, wherein the frequency selective surface comprises a periodic pattern and/or an aperiodic pattern.

4. The coated article according to claim 3, wherein the periodic pattern is selected from the group consisting of a periodic hexagonal lattice, a periodic square lattice, a periodic triangular lattice, a periodic circular lattice and a periodic Kagome lattice, and the aperiodic pattern is selected from a penrose tiling.

5. The coated article according to claim 1, wherein the frequency selective surface comprises a periodic pattern that has a unit cell dimension of less than about 2 mm and an aperture line width of about 5 μm to about 60 μm, for example about 30 μm to about 60 μm.

6. The coated article according to claim 5, wherein the frequency selective surface comprises a periodic pattern that has a unit cell dimension of about 0.5 mm and an aperture line width of about 50 μm.

7. The coated article according to claim 6, wherein the frequency selective surface comprises a periodic hexagonal lattice that has a unit cell dimension of about 0.5 mm and an aperture line width of about 50 μm.

8. The coated article according to claim 1, wherein the telecommunication frequency is for the fifth-generation (5G) communication.

9. The coated article according to claim 1, wherein the attenuation of telecommunication frequency signal transmission is reduced from about 30 dB to about 1 dB when compared with a coated article wherein the metallic layer bears no frequency selective surface.

10. The coated article according to claim 1, wherein the metallic layer comprises Ag, Al, Cu, Zn, Nb, TiN, Ag/Au alloys, Ag/Cu alloys, Ag/Al alloys, NbNₓ, NbCr, NbCrNₓ, NbZrOₓ, and/or Au.

11. The coated article according to claim 1, wherein the metallic layer has a thickness of about 5 nm to about 25 nm, preferably about 10 nm to about 20 nm.

12. The coated article according to claim 1, wherein the coated article comprises a low-E coating supported by a substrate, and the low-E coating comprises, in order outward from the substrate, a dielectric layer, a protective layer, a metallic IR reflective layer, a protective layer, and a dielectric layer.

13. (canceled)

14. A method of reducing attenuation of telecommunication frequency signal transmission for the coated article according to claim 1, wherein the method comprises creating a frequency selective surface on the metallic layer.

15. (canceled)

16. The method according to claim 14, wherein one or more stack is subjected to laser etching to create a frequency selective surface on the metallic layer and the one or more stack is selected from the following group: a stack of a substrate/a metallic layer, a stack of a substrate/a protective layer/a metallic layer, a stack of a substrate/a dielectric layer/a protective layer/a metallic layer, a stack of a substrate/a dielectric layer/a protective layer/a metallic layer/a protective layer, a substrate/a metallic layer/a substrate, a stack of a substrate/a protective layer/a metallic layer/a substrate, a stack of a substrate/a dielectric layer/a protective layer/a metallic layer/a substrate, and a stack of a substrate/a dielectric layer/a protective layer/a metallic layer/a protective layer/a substrate.

17. The method according to claim 16, wherein, for the laser etching, a laser beam enters from either side of the stack to create a frequency selective surface on the metallic layer.

18. The method according to claim 14, wherein a multiple pane window comprising a metallic layer is subjected to laser etching to create a frequency selective surface on the metallic layer.

19. The method according to claim 14, wherein a percentage of no more than about 25% area of the metallic layer is removed to create a frequency selective surface on the metallic layer.

20. The method according to claim 14, wherein a percentage of no more than about 20% area of the metallic layer is removed to create a frequency selective surface on the metallic layer.

21. The method according to claim 14, wherein a percentage of no more than about 10% area of the metallic layer is removed to create a frequency selective surface on the metallic layer.

22. (canceled)
